(19) United States
(12) Patent Application Publication
(10) Pub. No.: US 2003/0111739 A1
(43) Pub. Date: Jun. 19, 2003

(54) Semiconductor device and package thereof

(75) Inventors: Shigeo Kouzuki, Kawasaki-Shi (JP); Takao Emoto, Yokosuka-Shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/020,928

(22) Filed: Dec. 19, 2001

(51) Int. Cl. H01L 23/48

(52) U.S. Cl. 257/782

(57) ABSTRACT

A semiconductor device includes a semiconductor circuit which is formed inside; and an electrode structure which is formed on a first surface thereof. The electrode structure has a first electrode layer and a metal plating layer. The first electrode layer is formed of a first metal and is connected to the semiconductor circuit. The metal plating layer is formed of a second metal on the first electrode layer. The second metal is capable of being soldered on an extraction electrode outside of the semiconductor device.

### BACKGROUND OF THE INVENTION

1. Field of the Invention

The present invention relates to a semiconductor device and a package therefor.

2. Description of the Related Art

In recent years, the type of power semiconductor devices is being changed from the bipolar type to the high input impedance MOS type capable of miniaturizing drive circuits. Because problems that the physically workable dimension of a conventional MOS type semiconductor device is limited although its area efficiency can be increased if it adopts a small design rule, are being solved with the advance of working technique in recent years. It can be said that the MOS type having characteristics of a smaller switching loss than the bipolar type in theory has been accepted since the allowable loss efficiency is a problem in high power elements for switching.

The characteristics of a semiconductor device mainly depend on the design of its semiconductor chip. A MOS type high power semiconductor device is generally formed so that small elements are connected in parallel and current is perpendicularly extracted from the surface of a semiconductor chip to the reverse surface thereof (and vice versa). Therefore, it is important to enhance the area efficiency of a large number of small elements which are arranged on the surface of the semiconductor chip and to uniformly actuate all of the small elements in a balanced manner.

Referring to FIGS. 7 through 9, an example of a conventional MOS type semiconductor device will be described below. In the following figures the same reference numbers are given to the same portions and the descriptions thereof will be omitted.

FIG. 7 is a schematic sectional view of a semiconductor chip including a typical N-channel type power MOSFET having a maximum drain current of about 100 A and a maximum allowable loss of about 300 W.

The semiconductor chip 100 shown in FIG. 7 comprises an N⁺-type semiconductor substrate 1, an N-type drain layer 3 formed on the N⁺-type semiconductor substrate 1, a P-type base layer 5 formed in the surface portion of the N-type drain layer 3 and an N-type source layer 7 formed in the surface portion of the P-type base layer 5. The semiconductor chip 100 further comprises a trench type gate interconnection layer 13, AL (aluminum) electrodes 95 and 97 serving as external extraction electrodes and a drain electrode 19 which is formed on the reverse surface side of the N⁺-type semiconductor substrate 1.

In a typical method for fabricating the semiconductor chip 100 shown in FIG. 7, the N-type drain layer 3 is formed by the vapor phase epitaxy, and the P-type base layer 5 and the N-type source layer 7 are formed by the ion implantation method and thermal diffusion method. The gate interconnection layer 13 is formed by forming a gate oxide film 11 in the inner surface of a trench-shaped groove 9 which is formed so as to pass through the N-type source layer 7 and P-type base layer 5 and then by depositing polysilicon so as to be filled in the gate oxide film 11. The AL electrode 95 is formed in a gate region on the surface of the semiconductor chip 100 and the AL electrode 97 is formed in a source region thereon. The drain electrode 19 is formed of a metal layer of Ni or the like on the reverse surface of the N+-type semiconductor substrate 1 via a barrier metal 18.

When a potential is applied to the gate electrode 95, a portion of the P-type base layer 5 contacting the gate oxide film 11 is inverted to be N to form a channel for potentially connecting the N-type source layer 7 to the N-type drain layer 3, so that the P-type base layer 5 functions as a transistor. A large number of such small elements, i.e. cells, are continuously arranged and the trench grooves 9 are scaled down as small as possible to be arranged in the form of a mesh. The density of cells realized at present is about thirty millions per square inch and the development of further scaled-down products proceeds.

FIG. 8 is a plan view showing the arrangement of the source electrode and the gate electrode on the surface of the semiconductor chip 100 shown in FIG. 7. The gate portion of an integrated cell is connected to the gate electrode 95 via the gate interconnection layer 13. As shown in this figure, the source electrode 97 is arranged on the surface of the chip so as to have an area as large as possible in view of current characteristics.

Thus, the semiconductor chip 100 uses the trench type gate electrode to scale down the elements to reduce the on resistance.

FIG. 9A is a side view showing an example of a conventional package for semiconductor device wherein the semiconductor device chip 100 shown in FIG. 7 is incorporated, and FIG. 9B is a perspective view of the package for semiconductor device shown in FIG. 9. A frame radiating portion 51a of a frame 51 is fixed to the drain electrode on the reverse surface of the semiconductor chip 100 with a solder or conductive resin to serve as a drain terminal. On the other hand, the gate electrode 95 and the source electrode 97 on the top face of the semiconductor chip 100 are extended to external lead terminals 53 and 54 via wires 103 and 104 of AL or Au (gold), respectively. With respect to the semiconductor chip 100, the frame radiating portion 51a, wires 103 and 104, and all of connecting portions of external lead terminals 53 and 54 to the respective wires are covered with a sealing resin 56, and thereafter, processes for bending the frame 51 and the lead terminals 53 and 54, cutting the connecting portions thereof and so forth are carried out to form each of semiconductor devices.

As described above, with the advance of semiconductor working technique in recent years, the area efficiency of the semiconductor chip shown in FIG. 7 is also improved, so that a chip having a relatively small size can deal with a large current. Therefore, the semiconductor chip can be mounted in a small package.

However, the miniaturized package can take a sufficient connecting area to the external lead terminals. As a result, it is revealed that there is a problem in that the number of connecting wires is restricted. In addition, even if the current capacity is satisfied by increasing the number of wires, only a part of the source electrode is connected by the large number of wires, so that it is revealed that there is a problem in that the horizontal resistance of the source electrode itself is high. That is, it can be said that there is still room for improvement in characteristics.

As present solutions, the thickness of the AL electrode is changed from the conventional thickness of 2 to 3 μm to, e.g. about 10 μm, and the cross-sectional area in lateral directions is increased to decrease the resistance value, or the number of connecting wires is increased. However, as a semiconductor device product, there is a problem in that all methods increase material costs to bring about an increase in costs.

If the source electrode is formed of a plating metal of, e.g., Ni or Cu, by the wet plating method capable of relatively inexpensively forming the electrode, the source electrode can be soldered on a connecting plate 55 of, e.g., a Cu material having a large current capacity, like a package 300 for semiconductor device shown in FIG. 10, and the large area of the source electrode can be connected to the external lead terminals 53 and 54 via the connecting plate 55, so that it is expected that the current loss due to assembly structure can be reduced.

However, if the plating metal of Ni or Cu is formed directly on Si (silicon), there is the possibility that peeling phenomenon occurs on the interface, i.e., between Si and the plating metal, since the coefficient of thermal expansion of Si is different from the coefficient of thermal expansion of the heavy metal, such as Ni or Cu. In addition, as the influence of such an electrode of a plating metal arranged so as to contact Si, there are some cases where the distortion of Si crystal changes the characteristics of a semiconductor device and increases the leak current of a PN junction, for example. It is considered that one of causes thereof is the difference between coefficients of linear expansion (α) which are physical properties of Si and the metal (Ni: α=13.4, Cu: α=16.5, with respect to Si: α=2.6×10⁻⁶/at 20° C.). In order to eliminate the influence due to the difference in coefficient of linear expansion (α), a metal layer of W (tungsten: α=4.5) or Mo (molybdenum: α=4), which are metals having a close to that of Si (α=2.6×10⁻⁶/at 20° C.), is generally provided as a barrier metal via an alloy layer of the metal and Si. Also in this case, there is a problem in that the process is complicated to bring about an increase in costs.

### BRIEF SUMMARY OF THE INVENTION

According to a first aspect of the present invention, there is provided a semiconductor device comprising: a semiconductor circuit which is formed inside of the semiconductor device; and an electrode structure which is formed on a first surface of the semiconductor device, the electrode structure including a first electrode layer and a metal plating layer which is formed on the first electrode layer, the first electrode layer being formed of a first metal and connected to the semiconductor circuit, the metal plating layer being formed of a second metal, and the second metal being capable of being soldered onto an extraction electrode outside of the semiconductor device.

According to a second aspect of the present invention, there is provided a package for semiconductor device comprising: a semiconductor device including a semiconductor circuit and an electrode structure, the semiconductor circuit being formed inside of the semiconductor device, the electrode structure being formed on a first surface of the semiconductor device and having a first electrode layer and a metal plating layer which is formed on the first electrode layer, the first electrode layer being formed of a first metal and connected to the semiconductor circuit, the metal plating layer being formed of a second metal, the second metal being capable of being soldered onto an extraction electrode outside of the semiconductor device; a supporting substrate which supports thereon the semiconductor device; a lead terminal which is formed of a third metal and connected to the first electrode layer; and a metal plate which is formed of a fourth metal to serve as the extraction electrode and which connects the lead terminal to the first electrode layer via the metal plating layer.

According to a third aspect of the present invention, there is provided a package for semiconductor device comprising: a MOS type high power semiconductor device including a semiconductor circuit and an electrode structure, the semiconductor circuit being formed inside of the semiconductor device, the electrode structure being formed on a first surface of the semiconductor device and having a first electrode layer, a metal plating layer and a second electrode layer, the first electrode layer being formed of a first metal and connected to the semiconductor circuit, the metal plating layer being formed of a second metal on the first electrode layer, the second electrode layer being formed of a third metal on a second surface which is the opposite surface to the first surface, the second metal being capable of being soldered onto an extraction electrode outside of the semiconductor device, the first electrode layer and the metal plating layer forming at least one electrode of gate and source electrodes, and the second electrode layer forming a drain electrode; a frame plate which is formed of a fourth metal, supports the semiconductor device on the second surface and is connected to the second electrode layer; a lead terminal which is formed of a fifth metal and is connected to the first electrode layer; and a metal plate which is formed of a sixth metal to serve as the extraction electrode and which connects the lead terminal to the first electrode layer via the metal plating layer.

### BRIEF DESCRIPTION OF THE DRAWINGS

In the accompanying drawings:

FIG. 1 is a schematic sectional view showing a semiconductor chip which is an embodiment of a semiconductor device according to the present invention;

FIG. 2 is a graph showing the on resistance of the semiconductor chip shown in FIG. 1 in comparison with the prior art;

FIG. 3A is a side view showing an embodiment of a package for semiconductor device according to the present invention;

FIG. 3B is a perspective view of the package for semiconductor device shown in FIG. 3A;

FIG. 4 is a plan view of a conventional semiconductor chip for explaining the effects of the present invention;

FIG. 5 is a graph showing the values of resistance of an Au wire which is connected to the semiconductor chip shown in FIG. 4;

FIG. 6 is a graph showing the values of resistance of an Al interconnection on the surface of the semiconductor chip shown in FIG. 4;

FIG. 7 is a schematic sectional view of an example of a semiconductor chip including a conventional N-channel type power MOSFET;

FIG. 8 is a plan view showing the arrangement of source and gate electrodes on the surface of the chip shown in FIG. 7;

FIG. 9A is a side view showing an example of a conventional package for semiconductor device, in which the semiconductor device chip shown in FIG. 7 is incorporated;

FIG. 9B is a perspective view of the package for semiconductor device shown in FIG. 9A;

FIG. 10A is a side view showing another example of a conventional package for semiconductor device; and

FIG. 10B is a perspective view of the package for semiconductor device shown in FIG. 10A.

### DETAILD DESCRIPTION OF THE INVENTION

Referring now to the accompanying drawings, some embodiments of the present invention will be described below.

(1) Embodiment of Semiconductor Device

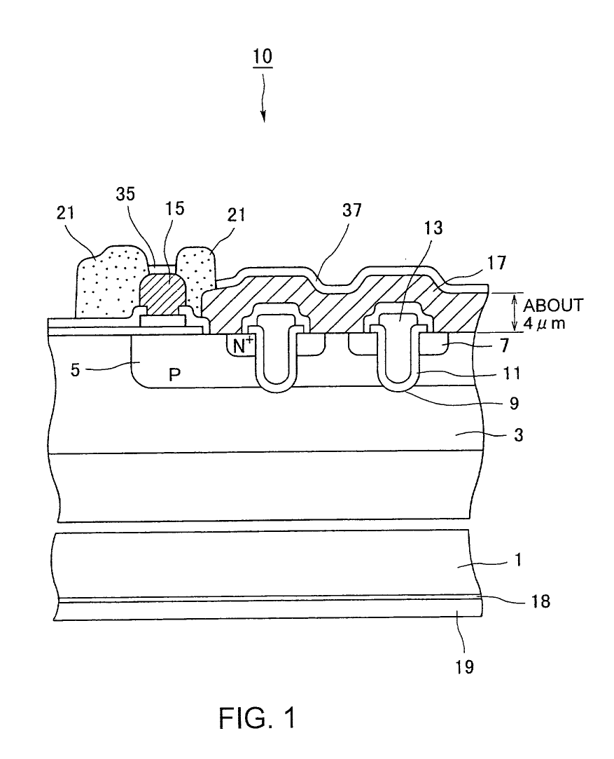

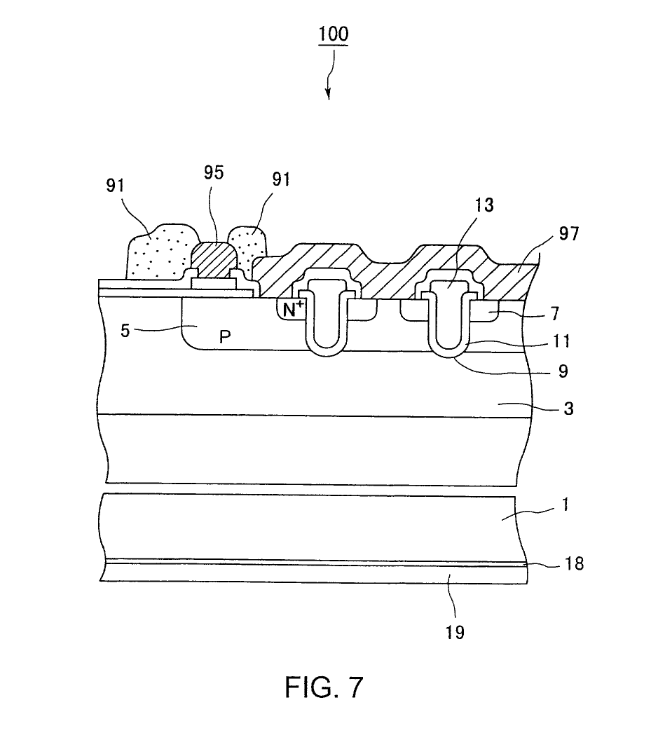

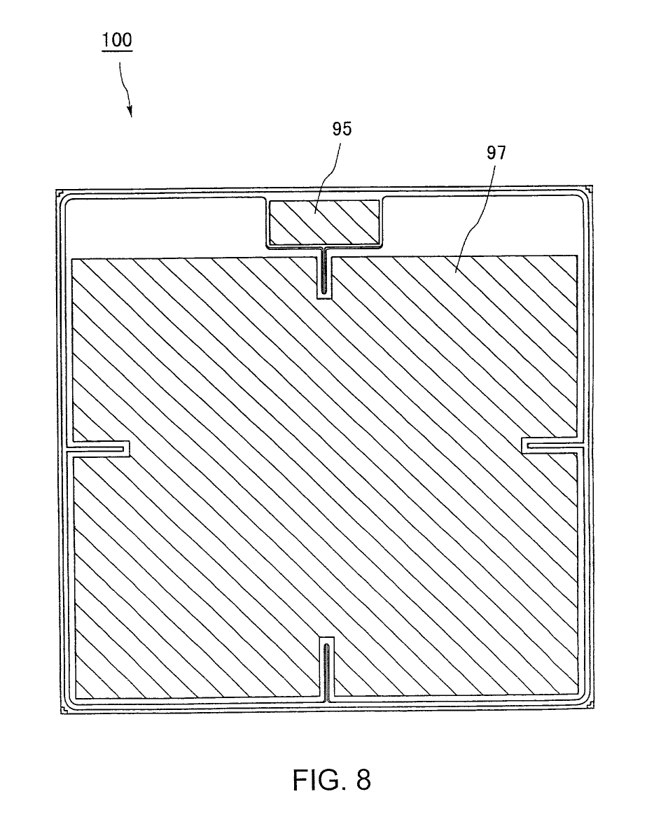

FIG. 1 is a schematic sectional view showing a semiconductor chip which is an embodiment of a semiconductor device according to the present invention. As can be clearly seen from the comparison with FIG. 7, the features of the semiconductor chip 10 shown in FIG. 1 are that AL layers 15 and 17 are formed so as to have a thickness of about 4 μm which is larger than 0.5 μm, and that metal plating layers 35 and 37 are formed on the AL layers 15 and 17, respectively, the AL layer 15 and the metal plating layer 35 constituting a gate electrode, and the AL layer 17 and the metal plating layer 37 constituting a source electrode. Other constructions of the semiconductor chip 10 are substantially the same as those of the semiconductor chip shown in FIG. 7.

In this embodiment, the metal plating layers 35 and 37 are formed by the plating processing of a metal, such as Ni (nickel) or Cu (copper), which is capable of being soldered. This plating processing is carried out by the electroless plating. Therefore, in a process for fabricating a semiconductor device, the processing can be carried out in a wafer state, and the metal plating layers 35 and 37 can be formed only on the surface of the AL electrode of a metal. Thus, according to this embodiment, the gate and source electrodes include the AL layers 15 and 17 of the same material as that of conventional AL layers, so that the softness (hardness) of AL prevents peeling from occurring on the interface to Si. In addition, the gate and source electrodes include the metal plating layers, which are formed of the metal capable of being soldered, as intermediary metals between the AL layers 15, 17 and external electrodes, so that a semiconductor device comprising an electrode structure having a low electrode resistance can be provided by a simple fabricating method.

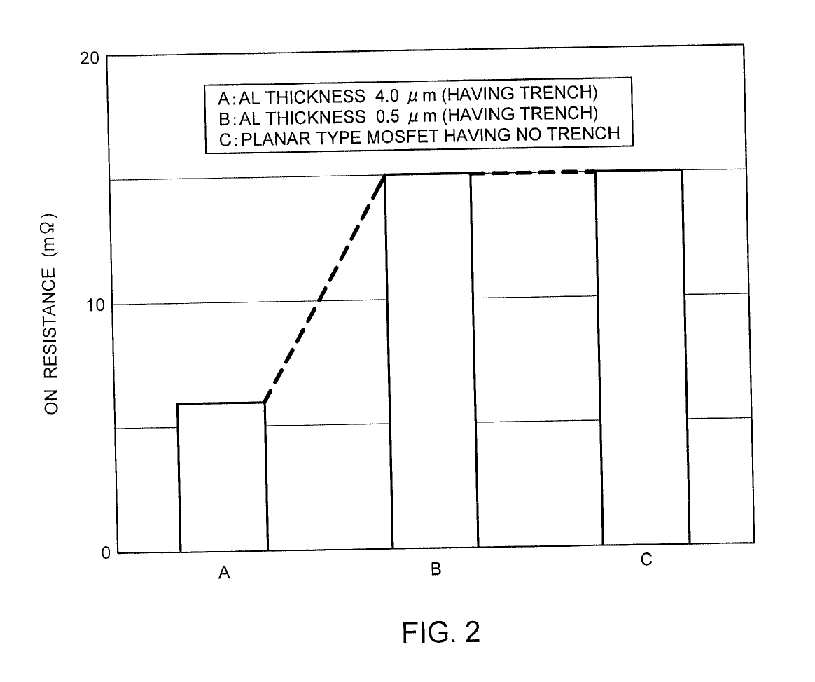

FIG. 2 is a graph showing the on resistance of the semiconductor chip 10 in comparison with that in the prior art by simulation. In this figure, A denotes the on resistance of the semiconductor chip 10 shown in FIG. 1. In addition, B denotes the on resistance when the thickness of the AL layers 15 and 17 of the semiconductor chip 10 is about 0.5 μm. Moreover, C denotes on resistance of a planar type MOSFET which includes an AL layer having a thickness of about 4 μm similar to the semiconductor chip 10 and which has no trench. Comparing A with B, it can be seen that the on resistance greatly decreases from about 15 mΩ to about 6mΩ by increasing the thickness of the AL layers 15 and 17 from 0.5 μm to about 4 μm. Comparing A with C, it can be seen that even if the thickness of the AL layer is the same, the semiconductor device can be further scaled down by providing the trench, so that the on resistance greatly decreases.

In addition, since the metal plating layers 35 and 37 are formed by a plating process, a PI (polyimide) layer 21 serving as a protective film can be used as a mask for plating. That is, by carrying out a plating processing after partially masking the surface of the AL layer with the PI layer 21, the metal plating layers 35 and 37 can be selectively formed only on the AL layer in a region other than a region which is covered with the PI layer. In a typical mask etching for Ni or Cu, it is required to carry out etching with a strong acid, so that a difficult processing, such as control of an etching rate, is often carried out. In this embodiment, the metal plating layers 35 and 37 can be formed by a very simple process by using the PI layer as a mask. As a result, it is possible to inexpensively fabricate a semiconductor device having a low electrode resistance.

The wet plating method, a so-called electroless plating method, maybe, e.g., a substitutional plating method or a chemical reducing plating method. The substitutional plating method is a method utilizing the difference in electrochemical order, i.e., a potential difference between different kinds of metals in a solution. The chemical reducing plating method is a method utilizing an example capable of carrying out a Cu (copper) plating on Fe (iron) in a copper sulfate solution, and an activation energy of a metal ion reduction due to force of a reducing agent, e.g., sodium hypophosphite. In general, Al₂O₃ (alumina) is formed on the surface of aluminum metal in the atmosphere due to its characteristics. Therefore, in this embodiment, in order to prevent the metal plating layer from being simply peeled off, the plating processing on the AL layers 15 and 17 is carried out after removing Al₂O₃ by a pretreatment. This pretreatment is preferably a so-called zincate treatment. This is a treatment for forming a thin Zn (zinc) layer on the surface of the AL layers 15 and 17 by the substitutional plating in order to form a strong plating bonding layer.

(2) Embodiment of Package for Semiconductor Device

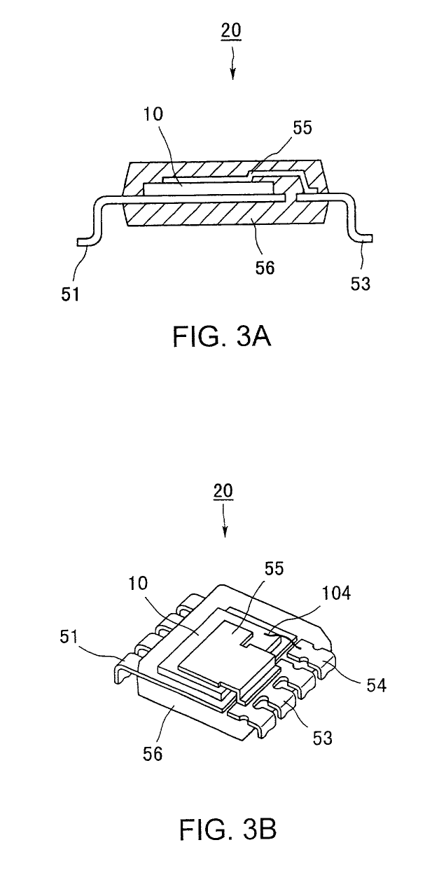

An embodiment of a package for semiconductor device according to the present invention is shown in FIGS. 3A and 3B. FIG. 3A is a side view showing a package 20 for semiconductor device in this embodiment, and FIG. 3B is its perspective view.

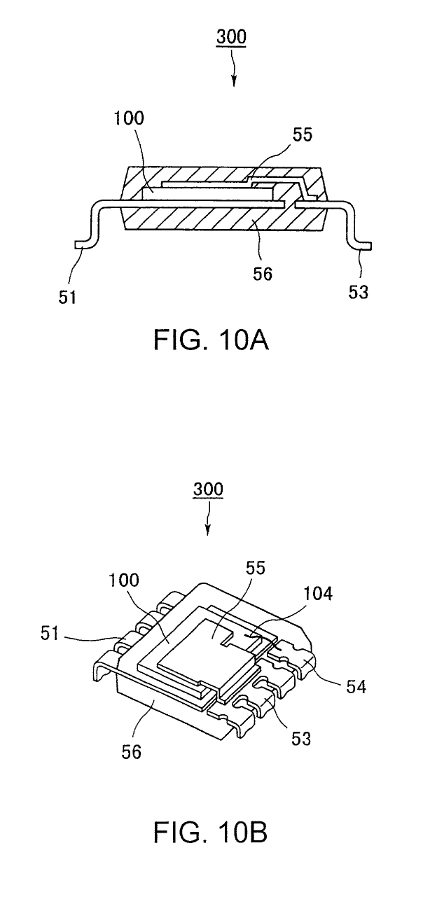

The above described semiconductor chip 10 is built into the package 20 for semiconductor device. As shown in FIG. 3B, the package 20 for semiconductor device comprises a connecting plate 55 for connecting an external lead terminal 53 to the source electrode 17 (see FIG. 1). The connecting plate 55 is formed by punching and cutting a Cu plate. As described above, the metal plating layer 37 (see FIG. 1) is formed on the surface of the source electrode 17 of the semiconductor chip 10, so that the connecting plate 55 is fixed to the metal plating layer 37 with a soldering or conductive resin. Therefore, the source electrode 17 of the semiconductor chip 10 is connected to the external lead terminal 53 via the metal plating layer 37 and connecting plate 55. In addition, the metal plating layer 35 (see FIG. 1) is formed on the surface of the gate electrode 15 of the semiconductor chip 10, so that the gate electrode 15 is connected to an external lead terminal 54 via the metal plating layer 35 and a gate wire 104. Other constructions of the package 20 for semiconductor device are substantially the same as those of the package 300 for semiconductor device shown in FIG. 10.

Thus, according to this embodiment, the above described semiconductor device according to the present invention is built into the package, the connecting plate of Cu or the like can be used for connecting the lead terminal of the package to the source electrode of the chip independent of a wire of AL or Au. Thus, it is possible to connect the whole surface of the source electrode to the external lead, so that it is possible to greatly reduce the electrode resistance.

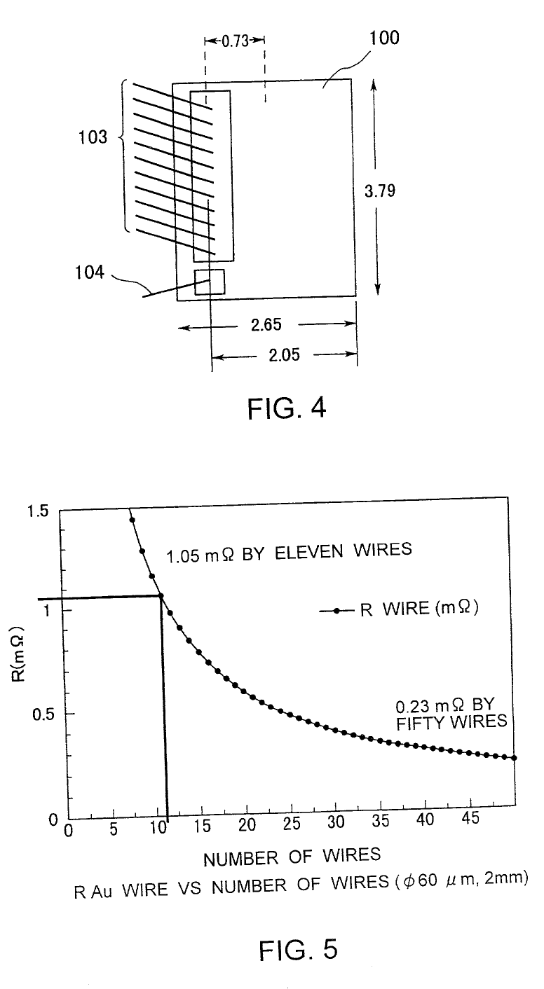

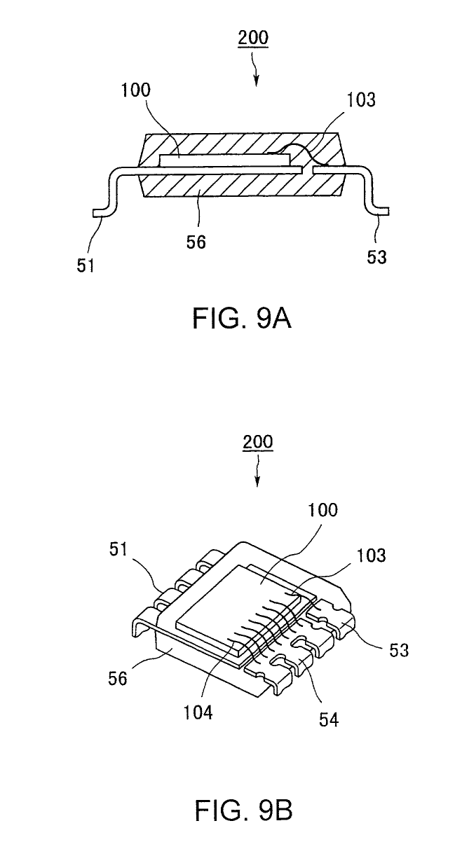

The chip on resistance of the package 20 for semiconductor device in this embodiment and the chip on resistance of the conventional package 200 for semiconductor device shown in FIG. 9 were calculated by simulation. As a result, the chip on resistance of the package 200 for semiconductor device was 8.3 mΩ on average, whereas the chip on resistance of the package 20 for semiconductor device was 6.0 mΩ on average. It can be seen from this that the chip on resistance was improved by 2.3 mΩ in this embodiment. This improvement of the value of resistance results from the above described electrode structure of the semiconductor device. Referring to FIGS. 4 through 7, this point will be described below.

FIG. 4 is a plan view showing a principal part of the package 200 for semiconductor device shown in FIG. 9. Each of eleven connecting wires 103 arranged in the package 200 for semiconductor device in parallel is a gold wire having 60 μmΦ and a length of 2 mm, and has a value of resistance of 11.5 mΩ. Therefore, as shown in the graph of FIG. 5, the value of resistance RAu wire_{All} of the whole wire 103 is as follows.

RAu wire_{All}=1.05 mΩ (1)

Then, the value of resistance of the AL wiring of the package 200 for semiconductor device is calculated. As shown in FIG. 4, the size of the semiconductor chip 100 has a width of 3.79 mm and a length of 2.65, and the size of the AL electrodes 15 and 17 has a width of 3.79 mm and a length of 2.05 as a whole. Its thickness is 4 μm. Assuming that the specific resistance of AL is ρAl=2.65E−6 (crystal AL), the whole value of resistance RAl of the AL electrodes 15 and 17 in longitudinal directions is RAl=1.748×2.05 (mm)=3.58 (mΩ)

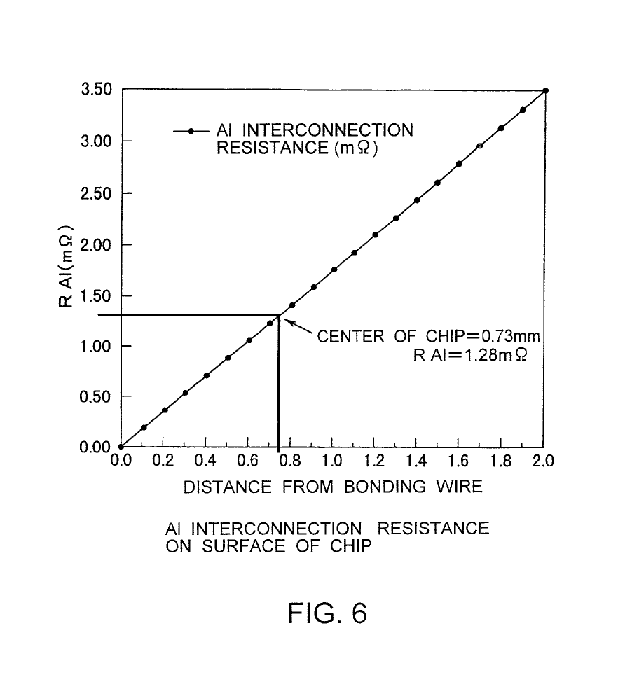

The distance between the wire connecting position and the center of the end portion of the source electrode 17 in an actual chip is about 0.73 mm. Therefore, also as shown in FIG. 6, the average value of resistance RAl_{Av} of the source electrode 17 in lateral directions is as follows.

RAl_{AV}=1.748×0.73 (mm)=1.28 (mΩ) (2)

Therefore, from expressions (1) and (2), the sum of the Au wire resistance and the AL electrode resistance is RAu wire_{All}+RAl_{AV}=1.05 mΩ+1.28mΩ=2.33mΩ, so that it is substantially coincident with the above described improvement value of the chip on resistance. This value occupies about 28% of the average chip on resistance 8.3 mΩ of the package 200 for semiconductor device. This indicates that the value of chip on resistance is improved by 28% in this embodiment.

While the embodiments of the present invention have been described, the present invention should not be limited to the above described embodiments, but the invention can be embodied in various ways without departing from its scope and spirit. For example, in the package for semiconductor device in the above described embodiment, in the respective connections of the external lead terminals to the gate and source electrodes, the AL layer (source electrode) 17 is connected to the external lead terminal 53 via the connecting plate 55. On the other hand, the AL layer (gate electrode) 15 is connected to the external lead 54 via the wire 104 since the current capacity of the gate electrode is small. However, the gate electrode 15 may be connected to the external lead 54 via, e.g., a stripe-shaped connecting plate, in place of the wire 104. In this case, since the contact area increases, the electrode resistance can be further reduced.

What is claimed is:

1. A semiconductor device comprising:
a semiconductor circuit which is formed inside of said semiconductor device; and
an electrode structure which is formed on a first surface of the semiconductor device,
said electrode structure including a first electrode layer and a metal plating layer which is formed on said first electrode layer, said first electrode layer being formed of a first metal and connected to said semiconductor circuit, said metal plating layer being formed of a second metal, and said second metal being capable of being soldered onto an extraction electrode outside of said semiconductor device.

2. A semiconductor device according to claim 1, which further comprises a protective film which is formed on said first surface,
wherein said metal plating layer is selectively formed in a region of said first electrode layer by using said protective film as a mask.

3. A semiconductor device according to claim 1, wherein said first metal is AL (aluminum), and said first electrode layer has a thickness of 0.5 μm or more.

4. A semiconductor device according to claim 2, wherein said first metal is AL (aluminum), and said first electrode layer has a thickness of 0.5 μm or more.

5. A semiconductor device according to claim 1, wherein said metal plating layer is formed by a wet electroless plating.

6. A semiconductor device according to claim 1, wherein said second metal includes at least one of Ni (nickel) and Cu (copper).

7. A semiconductor device according to claim 2, wherein said protective film is formed of PI (polyimide resin).

8. A semiconductor device according to claim 1, wherein said semiconductor device is a MOS type high power semiconductor device which further comprises a second electrode layer which is formed of a third metal on a second surface which is the opposite surface to said first surface,
said first electrode layer forms at least one electrode of gate and source electrodes, and
said second electrode layer forms a drain electrode.

9. A package for semiconductor device comprising:
a semiconductor device including a semiconductor circuit and an electrode structure, said semiconductor circuit being formed inside of said semiconductor device, said electrode structure being formed on a first surface of said semiconductor device and having a first electrode layer and a metal plating layer which is formed on said first electrode layer,
said first electrode layer being formed of a first metal and connected to said semiconductor circuit,
said metal plating layer being formed of a second metal, said second metal being capable of being soldered onto an extraction electrode outside of said semiconductor device;
a supporting substrate which supports thereon said semiconductor device;
a lead terminal which is formed of a third metal and connected to said first electrode layer; and
a metal plate which is formed of a fourth metal to serve as said extraction electrode and which connects said lead terminal to said first electrode layer via said metal plating layer.

10. A package for semiconductor device according to claim 9, which further comprises a protective film which is formed on said first surface,
wherein said metal plating layer is selectively formed in a region of said first electrode layer by using said protective film as a mask.

11. A package for semiconductor device according to claim 9, wherein said first metal is AL (aluminum), and said first electrode layer has a thickness of 0.5 μm or more.

12. A package for semiconductor device according to claim 9, wherein said metal plating layer is formed by a wet electroless plating.

13. A package for semiconductor device according to claim 9, wherein said second metal includes at least one of Ni (nickel) and Cu (copper).

14. A package for semiconductor device according to claim 10, wherein said protective film is formed of PI (polyimide resin).

15. A package for semiconductor device comprising:
a MOS type high power semiconductor device including a semiconductor circuit and an electrode structure, said semiconductor circuit being formed inside of said semiconductor device, said electrode structure being formed on a first surface of said semiconductor device and having a first electrode layer, a metal plating layer and a second electrode layer,
said first electrode layer being formed of a first metal and connected to said semiconductor circuit, said metal plating layer being formed of a second metal on said first electrode layer, said second electrode layer being formed of a third metal on a second surface which is the opposite surface to said first surface, said second metal being capable of being soldered onto an extraction electrode outside of said semiconductor device, said first electrode layer and said metal plating layer forming at least one electrode of gate and source electrodes, and said second electrode layer forming a drain electrode;
a frame plate which is formed of a fourth metal, supports said semiconductor device on said second surface of said semiconductor device and is connected to said second electrode layer;
a lead terminal which is formed of a fifth metal and is connected to said first electrode layer; and
a metal plate which is formed of a sixth metal to serve as said extraction electrode and which connects said lead terminal to said first electrode layer via said metal plating layer.

16. A package for semiconductor device according to claim 15, which further comprises a protective film which is formed on said first surface,
wherein said metal plating layer is selectively formed in a region of said first electrode layer by using said protective film as a mask.

17. A package for semiconductor device according to claim 15, wherein said first metal is AL (aluminum), and said first electrode layer has a thickness of 0.5 μm or more.

18. A package for semiconductor device according to claim 15, wherein said metal plating layer is formed by a wet electroless plating.

19. A package for semiconductor device according to claim 15, wherein said second metal includes at least one of Ni (nickel) and Cu (copper).

20. A package for semiconductor device according to claim 16, wherein said protective film is formed of PI (polyimide resin).
